(19) United States
(12) Patent Application Publication
(10) Pub. No.: US 2013/0297981 A1
(43) Pub. Date: Nov. 7, 2013

(54) LOW COST HIGH THROUGHPUT TSV/MICROBUMP PROBE

(71) Applicants: Shiqun Gu, San Diego, CA (US); Michael Laisne, San Diego, CA (US); Matthew M. Nowak, San Diego, CA (US); Glen T. Kim, San Diego, CA (US); Mark C. Chan, San Diego, CA (US); Hongjun Yao, San Diego, CA (US)

(72) Inventors: Shiqun Gu, San Diego, CA (US); Michael Laisne, San Diego, CA (US); Matthew M. Nowak, San Diego, CA (US); Glen T. Kim, San Diego, CA (US); Mark C. Chan, San Diego, CA (US); Hongjun Yao, San Diego, CA (US)

(73) Assignee: QUALCOMM INCORPORATED, San Diego, CA (US)

(21) Appl. No.: 13/537,528

(22) Filed: Jun. 29, 2012

Related U.S. Application Data
(60) Provisional application No. 61/641,121, filed on May 1, 2012.

(51) Int. Cl. G01R 31/3177

(52) U.S. Cl. CPC G01R 31/3177
USPC 714/727; 714/729; 714/724

(57) ABSTRACT

A first apparatus, such as a die or a semiconductor package, has signal paths extending through the apparatus. The signal paths can include through vias and other components. The signal paths are operable to communicate with a second apparatus when the second apparatus is stacked with the first apparatus. The first apparatus also has pass gates. Each pass gate is configurable in response to a signal, to short a pair of the signal paths to enable substantially simultaneous testing of the signal paths. The pass gates may be configurable to isolate the signal paths during operation of the first apparatus.

### RELATED APPLICATION

This application claims priority from and the benefit of U.S. Provisional Ser. No. 61/641,121, filed May 1, 2012.

### FIELD

The present disclosure generally relates to semiconductor device assembly and testing. More specifically, the present disclosure relates to efficiently testing dies before stacking and assembling.

### BACKGROUND

Current technology employs stacking semiconductor chips (e.g., microprocessors, digital signal processors, etc.). A 3D semiconductor device (or stacked IC device) can contain two or more semiconductor devices stacked vertically so they occupy less floor space than two or more conventionally arranged semiconductor devices. The stacked IC device is a single integrated circuit built by stacking dies or wafers (front silicon wafers) and/or ICs and interconnecting them vertically.

In some 3D stacks, through-substrate vias (TSVs) create vertical connections through the body of the semiconductor device. As their name suggests, TSVs are generally substantially vertical interconnects used to make electrical connections through a semiconductor. TSVs may include a conducting core and an insulating sleeve contained in a semiconductor substrate. By using TSV technology, stacked IC devices can pack a great deal of functionality into a small footprint. This TSV technique is sometimes also referred to as TSS (Through Silicon Stacking). TSVs are also referred to as through-silicon vias. With TSVs, critical electrical paths through the device can be drastically shortened, reducing capacitance and resistance and therefore improving system performance and reducing power consumption.

As die stacks become more complicated and are used more, issues of failure are presented. For 3D chip integration, if a good die is stacked to a had die, the whole stack would be bad. Ensuring that a die is good, before stacking is important. Like all ICs, these 3D stacked ICs are tested for manufacturing defects. Conventional test solutions include boundary scan testing, and include control and observation of special design-for-testability (DFT) features or circuitry.

During the process flow, the front side die functions can be checked through wafer level probing; however, microbump or TSV connectivity can not be verified by front side probing only. In order to test the microbumps or TSVs, probing on microbumps would be required; however, to get high connectivity between chips, the microbump count would be high. During testing, using each channel of a tester for probing each microbump would limit testing to one to two dies for each probing step, which results in inefficiencies of both time and cost of testing. Therefore, there is a need to develop methods and structures to enable such testing in a more efficient manner.

### SUMMARY

One aspect of the present disclosure provides a first apparatus having signal paths extending through the first apparatus. The signal paths are operable to communicate with a second apparatus when the second apparatus is stacked with the first apparatus. The first apparatus farther includes pass gates. Each pass gate is configurable in response to a signal, to short a pair of the signal paths to enable substantially simultaneous testing of the signal paths. The pass gates may be configurable to isolate the signal paths during operation of the first apparatus.

In another aspect, a method of testing signal paths in a device is provided. The method includes enabling at least one pass gate within a device. The pass gate facilitates coupling of the signal paths in a daisy chain configuration. The method also includes providing a testing signal to the daisy chained signal paths for substantially simultaneous testing of the signal paths.

Another aspect discloses a first apparatus including means for communicating with a second apparatus when the second apparatus is stacked with the first apparatus. The communicating means extends through the first apparatus. The first apparatus also includes a means for shorting a pair of the communicating means to enable substantially simultaneous testing of the pair of the communicating means. The shorting means may be configurable to isolate the pair of the communicating means during operation of the first apparatus.

This has outlined, rather broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

The features, nature, and advantages of the present disclosure will become more apparent from the detailed description set forth below when taken in conjunction with the drawings in which like reference characters identify correspondingly throughout.

FIG. 1A is a cross-sectional view of an integrated circuit (IC) undergoing back side testing, according to one aspect of the present disclosure.

FIG. 1B is a simplified cross-sectional view of the integrated circuit (IC) of FIG. 1A undergoing back side testing.

FIG. 2A is a cross-sectional view of another an IC undergoing front side testing, according to one aspect of the present disclosure.

FIG. 2B is a simplified cross-sectional view of the IC of FIG. 2A undergoing front side testing.

FIG. 3A is a cross-sectional view of another IC in a package on package configuration, according to one aspect of the present disclosure.

FIG. 3B is a top view of the IC of FIG. 3A.

FIG. 4 is a cross-sectional view of another IC with an interposer undergoing testing, according to one aspect of the present disclosure.

FIG. 5 is a block diagram illustrating a method for testing vias and microbumps of an integrated circuit, according to one aspect of the present disclosure.

FIG. 6 is a block diagram showing an exemplary wireless communication system in which a configuration of the disclosure may be advantageously employed.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

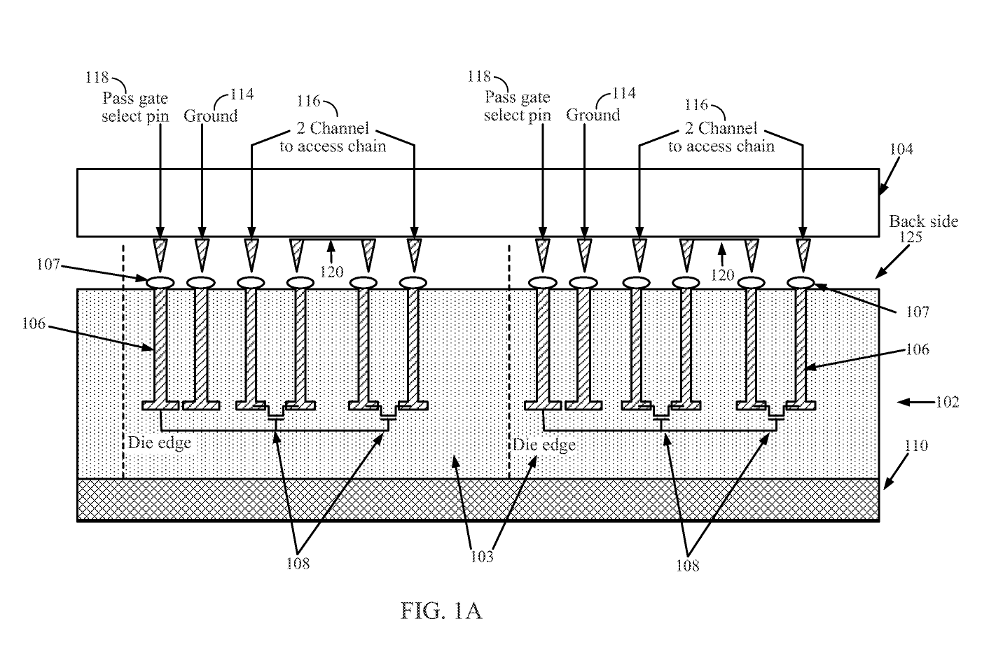

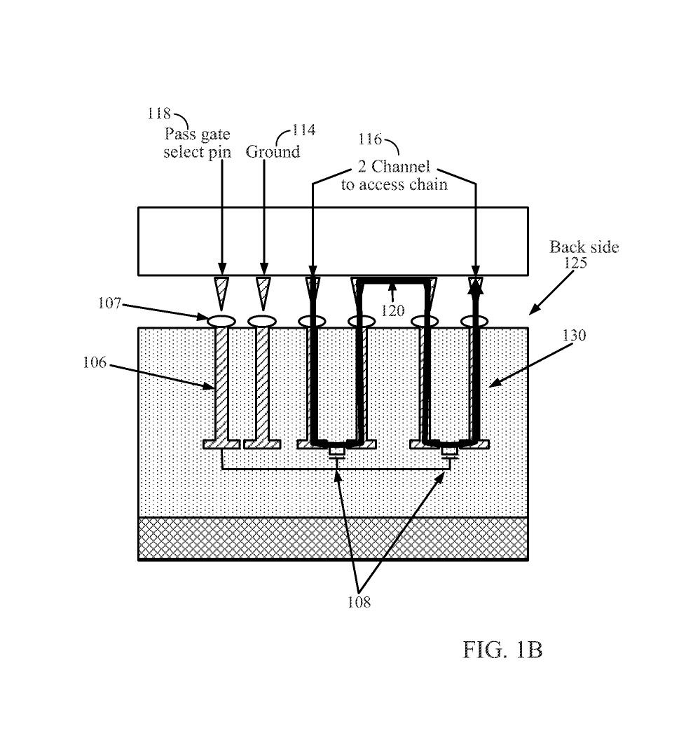

Configurations of the present application provide solutions that improve testing of ICs to be included in a stacked IC, from either the back side or front side. Note that when configurations of the present application are not in test inode, the die under test operates in normal mode (e.g. the through substrate vias operate as designed, which may include transmitting signals, as heat dissipation mechanisms, as electromagnetic shields, etc.) FIG. 1A shows a cross-sectional view illustrating dies 103 of a wafer 102 to be included in a 3D stacked integrated circuit (IC) package, a probe head or testing probe 104, and a supporting system 110 (e.g., a carrier, tape, chuck, etc.) for the thin wafer 102. TSVs 106 are provided within each die 103 of the wafer 102. Microbumps 107 couple to the TSVs 106, the microbumps 107 and TSVs 106 together may be referred to as a signal path. Other components may also be included in a signal path. Pass gates 108 are shown within the wafer 102 between pairs of TSVs 106. The dies 103 of the wafer 102 are shown in FIG. 1A in a back side testing configuration such that testing signals are being delivered from the back side 125 of the wafer 102 or dies 103. The dies includes active circuitry on the front side.

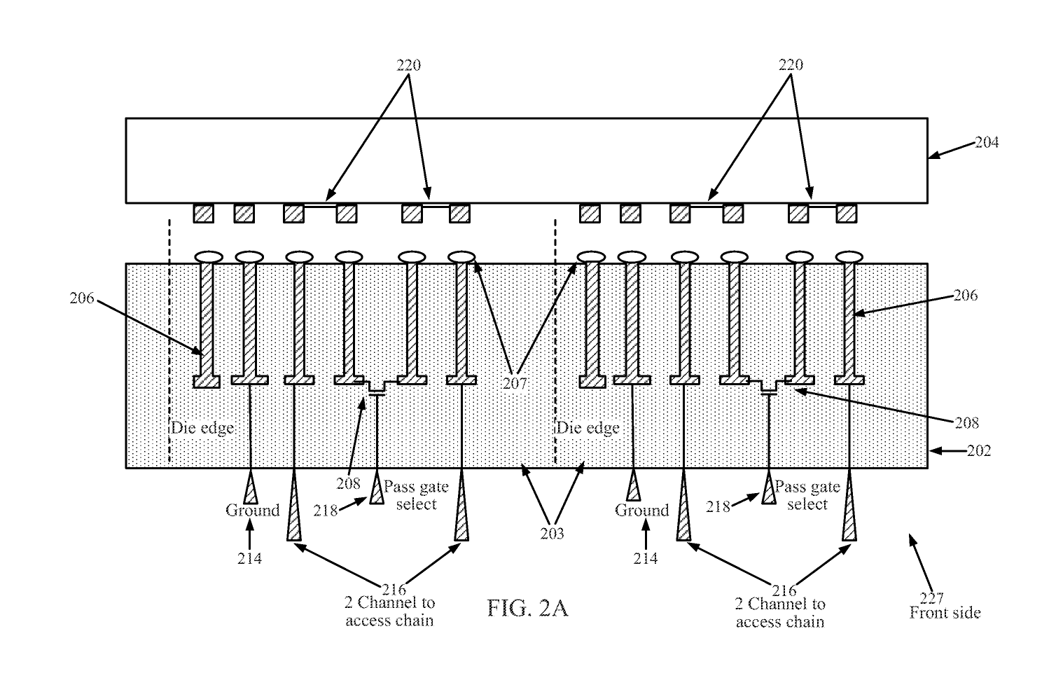

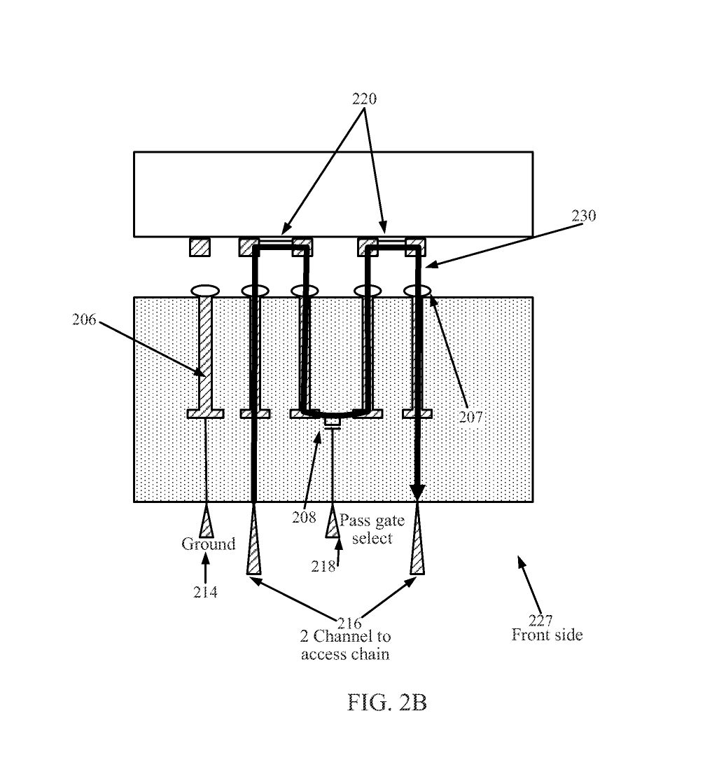

The figures and accompanying disclosure show a testing system that improves the testing of ICs. FIGS. 1A-2B show dies within wafers being tested. In some aspects, the dies are tested by providing a testing signal, from the active channel input to the active channel output, to either the front or back side of the die. FIGS. 1A and 1B show configurations of back side testing, where testing signals are provided from a back side of the die. FIGS. 2A and 2B show configurations of front side testing, where testing signals are provided from the side of the die with active circuitry. The signals provided during testing may include a power or pass gate select signal, to enable or disable pass gates within a die, two active testing channels, which function as the input and output of the test signal, and a ground connection.

When activated, the pass gates 108 short pairs of TSVs 106. In combination with the shorted pins creating the connection 120 on the testing probe 104, the activated pass gates 108 create TSV 106 and microbump 107 daisy chains. FIG. 1B shows a simplified view of the path 130 a testing signal would take while testing the daisy chained signal paths of FIG. 1A.

The daisy chains reduce the number of active channels used to test the signal paths, e.g., TSVs 106 and microbumps 107. Reducing or limiting the number of active channels for testing each die 103 reduces test costs and enables the testing of multiple dies or whole wafers during the same testing pass, thereby reducing testing time. Rather than testing only some TSVs 106 and microbumps 107 at one time, due to a limited number of channels available on test equipment, many or all TSVs 106 and microbumps 107 can be tested at once, using fewer channels. In some aspects, the pass gates 108 are only enabled during testing and are disabled during normal operation of the die 103. A pass gate select pin 118 activates or deactivates the pass gates 108. When the pass gates are disabled (during normal operation), the vias are isolated from each other.

In addition to a ground pin 114, and the pass gate select pin 118, only two channels are used to tests the daisy chained TSVs 106/microbumps 107. As shown by path 130 in FIG. 1B, a signal provided to one of the TSV access pins 116 progresses through the first microbump 107 and TSV 106, across the first pass gate 108 to the next TSV 106 and microbump 107, returning to the test probe 104. The signal then passes through the connection 120 created by shorted pins provided in the test probe 104 to the following microbump 107 and TSV 106, travelling through this microbump 107 and TSV 106, the attached pass gate 108, the adjacent TSV 106 and microbump 107 and returning to the second of the access pins 116.

Aspects of the present disclosure allow for access and testing of the signal paths, including the microbumps 107 and TSVs 106, of each die 103 with a reduced number of channels or active signals, allowing multiple die probing for each touch down. The testing includes connection, shorting, and leakage testing of the TSVs 106 and the microbumps 107. Although the configurations shown illustrate four TSV and microbump pairs being tested, any number of TSVs may be daisy chained together for testing. Additional pairs of signal paths, including TSVs and microbumps, can be added to the existing daisy chain with probe head connections and pass gates, such that the daisy chain is extended. Although additional probe head connections are provided to support additional signal paths, only two active channels still function as the test signal input and output for the daisy chain. To support the extra signal paths, the pass gate select pin would be coupled to any additional pass gates. In the event that a die employs an odd number of signal paths, such that the daisy chain would terminate on the opposite side of the die from where it began, an additional dummy signal path may be included to be paired with the last TSV so that the daisy chain will terminate on the same side of the die as it began.

Configurations of this disclosure can support the testing of single or multiple dies. By appropriately spacing the test pins to match the microbump pattern in adjacent dies, multiple dies can be tested simultaneously.

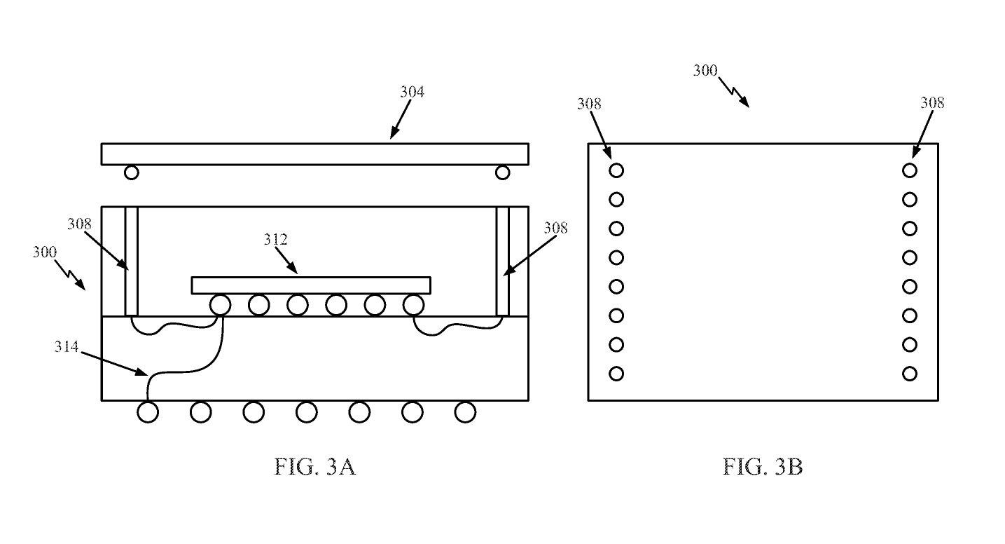

Other configurations of this disclosure enable efficient front side testing, for example, of devices to be included in package on package configurations. Although FIG. 2A shows a cross-sectional view illustrating a wafer 202 having two die 203 being tested, the device under test can also be an IC package to be included in a package on package (PoP) configuration, as explained with reference to FIGS. 3A-3B.

A testing probe head 204 allows front side 227 probing of the IC package 200. In some aspects, the probe head 204 has no active circuits. Rather, the probe head 204 functions to complete the TSV daisy chains. The probe head 204 is coupled to or a part of an overall testing apparatus including front side probe tips or pins 216-218. The probe head 204 has probe head connections 220 shorted together. The test probe heads are positioned in a configuration that matches the microbumps 207 of the die 203 to help create the daisy chains. Although a direct connection of the test pins 214-218 is shown, one of skill in the art would appreciate that in some configurations these pins are connected through a standard input-output circuit with electrostatic discharge protection.

Each die 203 includes one or more pass gates 208. The pass gates 208 allow daisy chaining of the TSVs 206/microbumps 207 in conjunction with the probe head connections 220 within the probe head 204. A pass gate select pin 218 enables or disables the pass gates 208 for testing purposes.

During testing or probing of the die 203, the probe head 204 is coupled to the microbumps 207 of the wafer 202. Next power is provided to each die 203 via the pass gate select pin 218 (closing the pass gates 208), and the ground pin 214 is coupled to ground. The signal paths, comprised of TSVs 206 and microbumps 207 and any other connection or component the signal may travel through, of each die 203 are then tested by a signal passed through the two TSV access channels 216 coupled to each die 203. This signal travels through all the TSVs 206 and microbumps 207 within the TSV chain of each die 203 created by daisy chaining the TSVs 206 and microbumps 207 using the enabled pass gates 208 and probe head connections 220. Configurations may allow for testing of the TSV connections, leakage, and detecting shorting. Shorts created by testing should be placed where shorts do not normally occur in order to avoid actual shorting. FIG. 2B shows a simplified view of the path 230 a testing signal would take while testing the daisy chained signal paths of FIG. 2A.

FIGS. 3A and 3B show a cross-sectional and top view, respectively, of a portion of a package 300 to be placed in a package on package (PoP) configuration, according to one aspect of this disclosure. In this configuration, for example, in FIG. 3A, through molding vias (TMVs) 308 are tested. Pass gates (not shown) are included in a die 312, for example a modem die 312 in this aspect, to facilitate creating of a daisy chain of through mold vias 308. When enabled, the pass gates couple some of the through mold vias. Connections in a probe head 304 are configured to complete the daisy chain configuration, similar to the configuration described with respect to FIGS. 2A and 2B. Connections 314 provide active signals, such as pass gate select, and two through mold via active channel signals, functioning as the input and output channels for the test signal, to the die 312 and the through mold vias 308 from below the die 312. A ground can also be provided.

As shown in FIG. 3B, the package 300 includes multiple through mold vias 308, which are hidden in the cross sectional view of FIG. 3B. Similar to the descriptions of other aspects of the present disclosure, pass gates and connection paths within a probe head 304 are employed to create a daisy chain of at least some of the through mold vias 308. The pass gates are activated by a pass gate select signal enabling the daisy chain. The die 312 is also provided a ground signal and at least two through mold via channel access signals, to enable the testing of the through mold vias 308. After testing is completed, the pass gate select channel disables the pass gates, allowing the through mold vias to return to their normal operational mode.

Another example of POP configuration testing is for copper pillars. The copper pillars are on a first package. The copper pillars are formed to couple to a second package not yet assembled onto the first package.

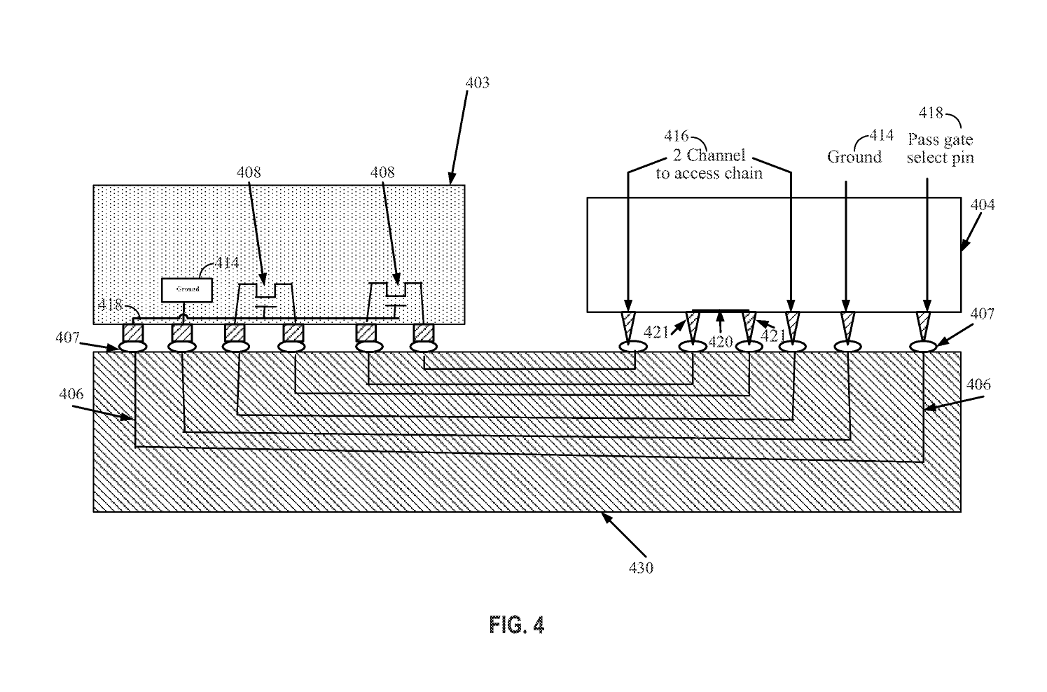

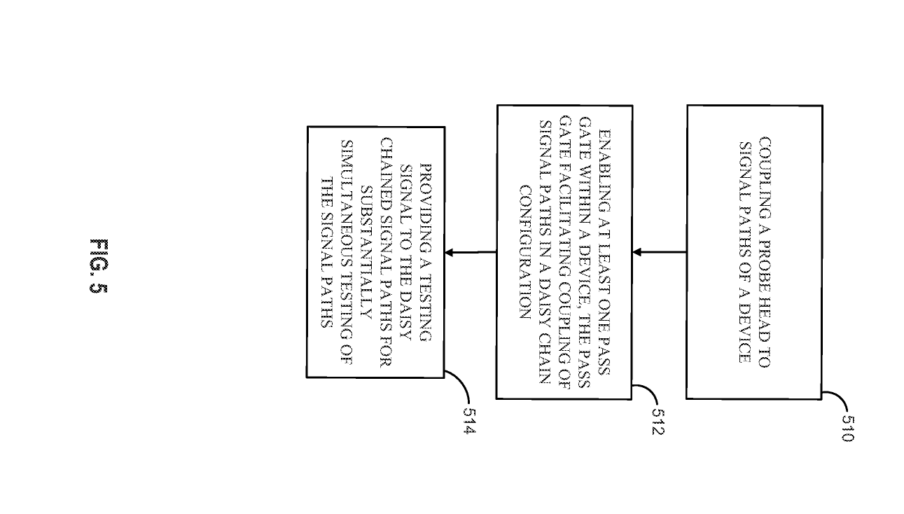

Other configurations of this disclosure enable efficient testing of signal paths including horizontal TSVs. For example, devices using an interposer configuration can be tested. Although FIG. 4 shows a cross-sectional view illustrating a die 403 being tested in conjunction with an interposer 430, the device under test can also be an IC package or any other device to be tested.

A testing probe head 404 allows probing of the interposer 430 and the die 403. The probe head 404 is coupled to the interposer 430 and provides signals 414-418 to the interposer 430 and thereby the die 403. The probe head 404 has a probe head connection 420 shorting pins 421 together to facilitate the formation of TSV 406 and microbump 407 daisy chains. The test probe head 404 is positioned in a configuration that matches the microbumps 407 of the interposer 430 with the pins 421. The die 403 is also positioned in a configuration that matches the microbumps 407 of the interposer 430 with the pins 421, to help create the daisy chains. Although a direct connection of the test pins 414-418 is shown, one of skill in the art would appreciate that in some configurations these pins are connected through a standard input-output circuit with electrostatic discharge protection.

Similarly to the configurations shown in FIGS. 1A-2B, the die 403 includes one or more pass gates 408. The pass gates 408 allow daisy chaining of the signal paths, including the TSVs 406/microbumps 407, in conjunction with the probe head connections 120 within the probe head 404. A pass gate select pin 418 enables or disables the pass gates 408 for testing purposes.

During testing or probing of the die 403 and interposer 430, the probe head 404 is coupled to the microbumps 407 of the interposer 430 and the die 403 is coupled to the microbumps of the interposer 430. The testing signals 414-118 are provided to the die 403 through the interposer 430. Though the die 403 of this configuration is not shown to have TSVs 406, other configurations may include TSVs in the die 403, such as those shown in the dies of FIGS. 1A-2B, which could also be tested. Power is provided to the die 403 via the pass gate select pin 118 (closing the pass gates 408), and the ground pin 414 is coupled to around. The signal paths, comprised of TSVs 406 and microbumps 407 and any other connection or component the signal may travel through, of the interposer 430 are then tested by a signal passed through the two signal path access channels 416 coupled to the interposer 430. This signal travels through all the TSVs 406 and microbumps 407 within the signal path chain of each interposer 430 and die 403 pair. Configurations may allow for testing of the TSV connections, leakage, and detecting shorting. Shorts created by testing should be placed where shorts do not normally occur in order to avoid actual shorting.

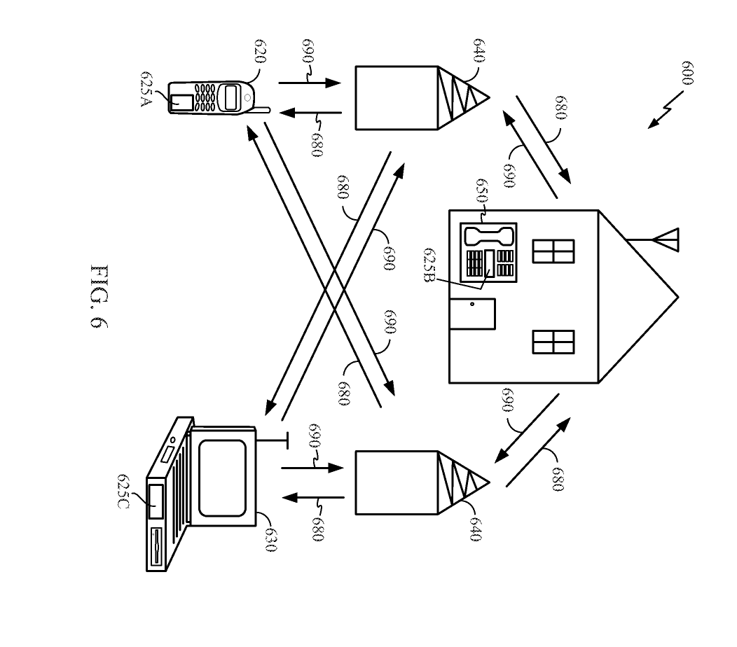

FIG. 5 illustrates a method for testing a device under test. In block 510, a probe head is coupled to the signal paths of a device. In block 512, at least one pass gate within a device under test is enabled, such that the pass gate(s) couples a set of signal paths in a daisy chain configuration, in combination with the probe head. In block 514, a testing signal is provided to the daisy chained signal paths for substantially simultaneous testing of the daisy chained signal paths. These methods may be carried out by the structures and components described above in relation to FIGS. 1, 2, 3A and 3A.

In one configuration, a first apparatus includes means for communicating with a second apparatus when the second apparatus is stacked with the first apparatus. The means for communicating extends through the first apparatus. In one aspect, the communicating means may be the signal paths including the TSVs 106/206, the microbumps 107/207/407, and/or the through mold vias (TMVs) 308. In this configuration, the first apparatus also includes means for shorting a pair of the communicating means to enable substantially simultaneous testing of the pair of the communicating means. The shorting means may be configured to isolate the pair of the communicating means during operation of the first apparatus. The shorting means may be the pass gates 108/208/408. In another aspect, the aforementioned means may be any component or any structure configured to perform the functions recited by the aforementioned means.

FIG. 6 shows an exemplary wireless communication system 600 in which a configuration of the disclosed testing method may be advantageously employed. For purposes of illustration, FIG. 6 shows three remote units 620, 630, and 650 and two base stations 640. It will be recognized that wireless communication systems may have many more remote units and base stations. Remote units 620, 630, and 650 include testing circuitry 625A, 625B, and 625C, respectively. FIG. 6 shows forward link signals 680 from the base stations 640 and the remote units 620, 630, and 650 and reverse link signals 690 from the remote units 620, 630, and 650 to base stations 640.

In FIG. 6, the remote unit 620 is shown as a mobile telephone, remote unit 630 is shown as a portable computer, and remote unit 650 is shown as a fixed location remote unit in a wireless local loop system. For example, the remote units may be cell phones, hand-held personal communication systems (PCS) units, portable data units such as personal data assistants, or fixed location data units such as meter reading equipment. Although FIG. 6 illustrates remote units, which may employ testing circuitry according to the teachings of the disclosure, the disclosure is not limited to these exemplary illustrated units. For instance, testing circuitry according to configurations of the present disclosure may be suitably employed in any device.

Although specific circuitry has been set forth, it will be appreciated by those skilled in the art that not all of the disclosed circuitry is required to practice the disclosed configurations. Moreover, certain well known circuits have not been described, to maintain focus on the disclosure. Similarly, although the relative terms “upper” and “lower” are used, these terms are non-limiting. For example if a device is rotated by 90 degrees the terms “upper” and “lower” would refer to “left most” and “right most” portions.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The steps of a method or algorithm described in connection with the disclosure herein may be embodied directly in hardware, in a software module executed by a processor, or in a combination of the two.

The methodologies described herein may be implemented by various components depending upon the application. For example, these methodologies may be implemented in hardware, firmware, software, or any combination thereof. For a hardware implementation, the processing units may be implemented within one or more application specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, electronic devices, other electronic units designed to perform the functions described herein, or a combination thereof.

For a firmware and/or software implementation, the methodologies may be implemented with modules (e.g., procedures, functions, and so on) that perform the functions described herein. Any machine-readable medium tangibly embodying instructions may be used in implementing the methodologies described herein. For example, software codes may be stored in a memory and executed by a processor unit. Memory may be implemented within the processor unit or external to the processor unit. As used herein the term “memory” refers to any type of long term, short term, volatile, nonvolatile, or other memory and is not to be limited to any particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be any available medium that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to store desired program code in the form of instructions or data structures and that can be accessed by a computer; disk and disc, as used herein, includes compact disc (CD), laser disc, optical disc, digital versatile disc (MD), floppy disk and blu-ray disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular embodiments of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A first apparatus, comprising:
a plurality of signal paths extending through the first apparatus and operable to communicate with a second apparatus when the second apparatus is stacked with the first apparatus; and
a plurality of pass gates, each pass gate configurable in response to a signal, to short a pair of the plurality of signal paths to enable substantially simultaneous testing of the plurality of signal paths.

2. The first apparatus of claim 1, in which the plurality of signal paths are operable to couple with a probe head to enable the substantially simultaneous testing.

3. The first apparatus of claim 1, farther comprising active circuitry on a front side of the first apparatus, which comprises a die, the front side being opposite to a back side having microbumps, the front side being operable to receive the signal,
wherein the plurality of signal paths comprise the microbumps and through substrate vias.

4. The first apparatus of claim 1, farther comprising active circuitry on a front side of the first apparatus, which comprises a die, the front side being opposite to a back side having microbumps, the back side operable to receive the signal,
wherein the plurality of signal paths comprise the microbumps and through substrate vias.

5. The first apparatus of claim 4, further comprising an interposer coupled to the die, the plurality of signal paths extending through the interposer.

6. The first apparatus of claim 1, in which the first apparatus comprises a semiconductor package and the plurality of signal paths comprise through mold vias extending through mold compound of the package.

7. The first apparatus of clan 6, further comprising a die within the package, the die including the plurality of pass gates, the die being configured to receive the signal.

8. The first apparatus of claim 6, farther comprising package to package connections coupled to the through mold vias, the package to package connections being configured to couple with a probe head to enable testing of the through mold vias.

9. The first apparatus of claim 1, in which the plurality of pass gates are configurable to isolate the plurality of signal paths during operation of the first apparatus

10. The first apparatus of claim 1, integrated into a mobile phone, a set top box, a music player, a video player, an entertainment unit, a navigation device, a computer, a hand-held personal communication systems (PCS) unit, a portable data unit, and/or a fixed location data unit.

11. A method of testing signal paths in a device, comprising:
enabling at least one pass gate within the device, the pass gate facilitating coupling of a plurality of signal paths in a daisy chain configuration; and
providing a testing signal to the plurality of signal paths in the daisy chain configuration for substantially simultaneous testing of the plurality of signal paths.

12. The method of claim 11, further comprising completing the daisy chain configuration by coupling a probe head to the device.

13. The method of claim 11, further comprising providing the testing signal to a back side of the device, in which the device comprises a die.

14. The method of claim 11, further comprising providing the testing signal to an front side of the device, in which the device comprises a die.

15. The method of claim 11, further comprising providing the testing signal to a die within the device, which comprises a semiconductor package.

16. The method of claim 11, further comprising integrating the device into a mobile phone, a set top box, a music player, a video player, an entertainment unit, a navigation device, a computer, a hand-held personal communication systems (PCS) unit, a portable data unit, and/or a fixed location data unit.

17. A first apparatus, comprising:
means for communicating with a second apparatus when the second apparatus is stacked with the first apparatus, the means for communicating extending through the first apparatus; and
means for shorting a pair of the communicating means to enable substantially simultaneous testing of the pair of the communicating means.

18. The first apparatus of claim 17, further comprising active circuitry on a front side of the first apparatus, which comprises a die, the front side being opposite to a back side having microbumps, the front side being operable to receive a testing signal,
wherein the pair of the communicating means comprise the microbumps and through substrate vias.

19. The first apparatus of claim 17, further comprising active circuitry on a front side of the first apparatus, which comprises a die, the front side being opposite to a back side having microbumps, the back side being operable to receive a testing signal,
wherein the pair of the communicating means comprise the microbumps and through substrate vias.

20. The first apparatus of claim 17, in which the first apparatus comprises a semiconductor package and the pair of the communicating means comprise through mold vias extending through mold compound of the package.

21. The first apparatus of claim 20, further comprising a die within the package, the die including the shorting means, the die being configured to receive a testing signal.

22. The apparatus of claim 17, in which the shorting means further comprises means for isolating the pair of the communicating means during operation of the first apparatus.

23. The first apparatus of claim 17, further comprising integrating the first apparatus into a mobile phone, a set top box, a music player, a video player, an entertainment unit, a navigation device, a computer, a hand-held personal communication systems (PCS) unit, a portable data unit, and/or a fixed location data unit.
